(19) United States
(12) Patent Application Publication
(10) Pub. No.: US 2026/0076243 A1
(43) Pub. Date: Mar. 12, 2026

(54) DIE FLIP BONDING DEVICE AND SEMICONDUCTOR PACKAGE MANUFACTURING METHOD

(71) Applicant: Samsung Electronics Co., Ltd., Suwon-si (KR)

(72) Inventors: Heesung PARK, Suwon-si (KR); Youngkyu BAE, Suwon-si (KR); Minwoo SONG, Suwon-si (KR); Jongho LEE, Suwon-si (KR); Hyunmin JEON, Suwon-si (KR)

(73) Assignee: Samsung Electronics Co., Ltd., Suwon-si (KR)

(21) Appl. No.: 19/083,640

(22) Filed: Mar. 19, 2025

(30) Foreign Application Priority Data
Sep. 12, 2024 (KR) 10-2024-0124465

(51) Int. Cl. H01L 23/00

(52) U.S. Cl. CPC H10W 72/0711; H10W 72/073; H10W 72/07173; H10W 72/07331; H10W 72/07338

(57) ABSTRACT

A die flip bonding device includes a substrate holder configured to provide a substrate including a plurality of die stacks having a gap in a first direction, the plurality of die stacks being wire-bonded; a first moving body configured to move to a first position to pick up a first uppermost die of a first die stack, among the plurality of die stacks, and then half-flip the first uppermost die in the first direction to move the first uppermost die to a second position; and a second moving body configured to move to the second position to receive the first uppermost die of the first die stack from the first moving body, and after the movement of the first moving body, half-flip the first uppermost die of the first die stack in the first direction at the second position to move the first uppermost die to a third position.

### CROSS-REFERENCE TO RELATED APPLICATION(S)

This application claims benefit of priority to Korean Patent Application No. 10-2024-0124465 filed on Sep. 12, 2024 in the Korean Intellectual Property Office, the disclosure of which is incorporated herein by reference in its entirety.

### BACKGROUND

The present inventive concepts relates to die flip bonding devices and methods for manufacturing a semiconductor package, and more particularly, to die flip bonding devices and semiconductor package manufacturing methods, flipping an uppermost die of a stacked die sequentially disposed on a substrate and already wire-bonded to the substrate, and moving and bonding the uppermost die to an uppermost die of an adjacent stacked die adjacent thereto.

Due to the rapid development of the electronics industry and the demands of users, electronic products are becoming increasingly smaller and lighter, and for this purpose, semiconductor packages mounted on electronic products are desired to have increasingly smaller volumes while including various functions.

Packaging technology for an integrated circuit die (hereinafter referred to as a “die”) may be continuously developing to satisfy demands for miniaturization and mounting reliability. Methods for mounting the die on a substrate may include wire-bonding using a wire, and a ball grid array (BGA) using a solder ball.

In order for a semiconductor chip package to perform various functions, a semiconductor of a package-on-package (POP) may be developed in which a plurality of dies are stacked or a semiconductor chip package is stacked on a different semiconductor chip package.

The plurality of dies may be wire-bonded on the substrate on which a redistribution line is formed, there may be a problem in that a height of a mold increases due to a problem that wires are disposed above an upper surface of an uppermost die, making it difficult to reduce a volume thereof.

In addition, in order to reduce a height of the semiconductor package, semiconductor packages of flip chips are being developed one after another in which the die or semiconductor package is flipped and mounted.

A pick-up device for moving a die of a conventional flip chip bonding device that manufactures a semiconductor package of a flip chip shape picks up the die and moves the die vertically and horizontally. A flip chip bonding device that manufactures a semiconductor package of a flip chip shape according to some example embodiments may include a flip pick-up device that may pick up a die and flips the die 180°, and a pick-up device that picks up a die flipped by the flip pick-up device and moves the die horizontally and vertically. In any case of a flip chip bonding device, there may be a problem that the wire is disconnected due to a wire loop gap located above the die, when flipping a die or a semiconductor package, wire-bonded to a substrate.

### SUMMARY

Some aspects of the present inventive concepts are to provide flip chip bonding devices capable of flipping an uppermost die, without damaging a wire, in a die stack in which a substrate and a die are already wire-bonded.

An aspect of the present inventive concepts are to provide flip chip bonding devices automatically manufacturing a semiconductor package in which an uppermost die is flipped down and a lower surface of the uppermost die is connected to a substrate, thereby reducing a volume.

Some aspects of the present inventive concepts are to provide methods for manufacturing a semiconductor package that manufactures a semiconductor package reducing a volume in which a lower surface of an uppermost die is connected to a substrate, by using a plurality of die stacks wire-bonded to the substrate and sequentially disposed on the substrate.

According to some aspects of the present inventive concepts, a die flip bonding device includes a substrate holder configured to provide a substrate including a plurality of die stacks having a gap in a first direction, the plurality of die stacks being wire-bonded; a first moving body configured to move to a first position to pick up a first uppermost die of a first die stack, among the plurality of die stacks, and then half-flip the first uppermost die in the first direction to move the first uppermost die to a second position; and a second moving body configured to move to the second position to receive the first uppermost die of the first die stack from the first moving body, and after the movement of the first moving body, half-flip the first uppermost die of the first die stack in the first direction at the second position to move the first uppermost die to a third position above an uppermost die of a second die stack, among the plurality of die stacks.

According to some aspects of the present inventive concepts, a die flip bonding device for flipping and stacking an uppermost die of at least one die stack onto an uppermost die of an adjacent die stack, in a plurality of die stacks in which a substrate is connected to a plurality of dies stacked on the substrate by wire-bonding, includes a first moving body configured to simultaneously move upwards in a first direction and a second direction, perpendicular to the first direction, to pick up an uppermost die of a first die stack, among the plurality of die stacks, to half-flip the picked uppermost die toward a second die stack adjacent thereto; and a second moving body configured to simultaneously move downwards in the first direction and the second direction, to receive the half-flipped uppermost die of the first die stack to half-flip the received uppermost die on an upper surface of an uppermost die of the second die stack.

According to some aspects of the present inventive concepts, a method for manufacturing a semiconductor package, includes bonding a substrate and a first die using a first adhesive film on the substrate; bonding the first die and an uppermost die using the first adhesive film on the first die and a second adhesive film on the first adhesive film; wire-bonding the first die and the uppermost die to the substrate; mounting an uppermost die of a first die stack on an upper surface of an uppermost die of a second die stack adjacent thereto by picking up the uppermost die of the first die stack and flipping the picked uppermost die in a direction of performing the flipping; and molding the substrate, and sawing and separating each of the die stacks.

According to some aspects of the present inventive concepts, a method for manufacturing a semiconductor package, includes simultaneously or continuously bonding a substrate and a first die using a first adhesive film on the substrate; simultaneously or continuously bonding an uppermost die on the first die and a second adhesive film on the first adhesive film, on the first die, to form a plurality of die stacks on the substrate; wire-bonding the first die and the uppermost die of the plurality of die stacks to the substrate; mounting the uppermost die of the plurality of die stacks on an upper surface of an uppermost die of an adjacent die stack by picking up the uppermost die using the die flip bonding device of claim 1 and flipping the picked uppermost die in a direction of performing the flipping; and molding the substrate, and sawing and separating each of the die stacks.

In addition, in methods for manufacturing a semiconductor package according to some example embodiments, the bonding a substrate and a first die and the bonding the first die and an uppermost die may be performed using the first adhesive film, to be heated to a temperature of 120° C. or less.

In addition, in methods for manufacturing a semiconductor package according to some example embodiments, after the mounting, bonding the uppermost die of the adjacent second die stack and the flipped uppermost die may be performed using the second adhesive film, to be heated to a temperature of 150° C. or less.

In addition, in methods for manufacturing a semiconductor package according to some example embodiments, an uppermost die adjacent to an end portion of the substrate in the direction of performing the flipping may include a dummy die, and wherein the dummy die may not be bonded to the substrate by wire-bonding.

In addition, in methods for manufacturing a semiconductor package according to some example embodiments, the dummy die may be flipped and collected in a dummy die collection box.

In addition, in methods for manufacturing a semiconductor package according to some example embodiments, the first die may include a plurality of dies bonded using the first adhesive film.

According to some aspects of the present inventive concepts, a method for manufacturing a semiconductor package, includes simultaneously or continuously bonding a substrate and a first die using a first adhesive film on the substrate; simultaneously or continuously bonding an uppermost die on the first die and a second adhesive film on the first adhesive film, on the first die, to form a plurality of die stacks on the substrate; wire-bonding the first die and the uppermost die of the plurality of die stacks to the substrate; mounting the uppermost die of the plurality of die stacks on an upper surface of an uppermost die of an adjacent die stack by picking up the uppermost die using the die flip bonding device of claim 1 and flipping the picked uppermost die in a direction of performing the flipping; and molding the substrate, and sawing and separating each of the die stacks.

In addition, in methods for manufacturing a semiconductor package according to some example embodiments, the bonding a substrate and a first die and the bonding the first die and an uppermost die may be performed using the first adhesive film, to be heated to a temperature of 120° C. or less.

In addition, in methods for manufacturing a semiconductor package according to some example embodiments, after the mounting, bonding the uppermost die of the adjacent second die stack and the flipped uppermost die may be performed using the second adhesive film, to be heated to a temperature of 150° C. or less.

In addition, in methods for manufacturing a semiconductor package according to some example embodiments, an uppermost die adjacent to an end portion of the substrate in the direction of performing the flipping may include a dummy die, and wherein the dummy die may not be bonded to the substrate by wire-bonding.

In addition, in a method for manufacturing a semiconductor package according to some example embodiments, the dummy die may be flipped and collected in a dummy die collection box.

### BRIEF DESCRIPTION OF DRAWINGS

The above and other aspects, features, and advantages of the present inventive concepts will be more clearly understood from the following detailed description, taken in conjunction with the accompanying drawings, in which:

FIG. 1 is a perspective view schematically illustrating a die flip bonding device according to some example embodiments.

FIG. 2 is a schematic cross-sectional view along line A-A′ of FIG. 1.

FIG. 3 is a cross-sectional view schematically illustrating a state in which an uppermost die of a die stack is flipped through a die flip bonding device.

FIG. 4A is a schematic perspective view illustrating a state in which a first moving body moves to a first position and adsorbs a first uppermost die.

FIG. 4B is a schematic perspective view illustrating a state in which a first moving body moves to a second position and half-flips a first uppermost die.

FIG. 4C is a schematic perspective view illustrating a state in which a second moving body moves to a second position and receives a first uppermost die from a first moving body.

FIG. 4D is a schematic perspective view illustrating a state in which a first moving body moving while maintaining a state in which a second moving body receives a first uppermost die from a second position.

FIG. 4E is a schematic perspective view illustrating a state in which a second moving body half-flips a first uppermost die from a second position to a third position on an upper surface of a second uppermost die of an adjacent die stack.

FIG. 5 is a schematic perspective view of a die flip bonding device including a third moving body controlling a movement range of a second moving body.

FIG. 6 is a schematic perspective view illustrating a plurality of first moving bodies, a plurality of second moving bodies, and a plurality of third moving bodies in a die flip bonding device.

FIG. 7 is a flow chart of a method for manufacturing a semiconductor package according to some example embodiments.

FIG. 8 is a schematic cross-sectional view illustrating a process of mounting a die on a substrate, in a method for manufacturing a semiconductor package according to some example embodiments.

FIG. 9 is a schematic cross-sectional view illustrating a process of stacking an uppermost die on a die, in a method for manufacturing a semiconductor package according to some example embodiments.

FIG. 10 is a schematic cross-sectional view illustrating a process of wire-bonding the stacked die of FIG. 9 and a substrate, in a method for manufacturing a semiconductor package according to some example embodiments.

FIG. 11 is a schematic cross-sectional view illustrating a process of stacking an uppermost die after a plurality of dies are stacked, in a method for manufacturing a semiconductor package according to some example embodiments.

FIG. 12 is a schematic cross-sectional view illustrating a process of wire-bonding the plurality of dies and the substrate of FIG. 10, in a method for manufacturing a semiconductor package according to some example embodiments.

FIG. 13 is a schematic cross-sectional view illustrating a process of flipping and mounting an upper die of a stacked die on an upper surface of an adjacent die stack, in a method for manufacturing a semiconductor package according to some example embodiments.

FIG. 14 is a schematic cross-sectional view illustrating a process of molding and sawing a die stack on an upper portion of a substrate, in a method for manufacturing a semiconductor package according to some example embodiments.

FIG. 15 is a schematic cross-sectional view of a semiconductor package manufactured by a method for manufacturing a semiconductor package according to some example embodiments.

### DETAILED DESCRIPTION

Hereinafter, example embodiments will be described with reference to the attached drawings.

Example embodiments may be modified in various different forms, and may be provided to explain to a person having average knowledge in the art more completely. Therefore, shapes and sizes of elements in the drawings may be exaggerated for clear explanation, and elements indicated by the same or similar symbols in the drawings refer to the same elements.

In the present inventive concepts, the meaning of “connection” includes not only “directly connected” but also “indirectly connected” through other configurations. In addition, it includes “electrically connected” in some cases.

In the present inventive concepts, expressions such as “first,” “second,” and the like may be used to distinguish one component from another component, and do not limit the order and/or importance of components corresponding thereto. In some cases, without exceeding the scope of the rights, a first component may be named a second component, and similarly, the second component may be named the first component. The terms used in the present inventive concepts may be used only to describe an example, and are not intended to limit the present inventive concepts. In this case, a singular expression includes a plural expression unless the context clearly indicates otherwise.

### Die Flip Bonding Device

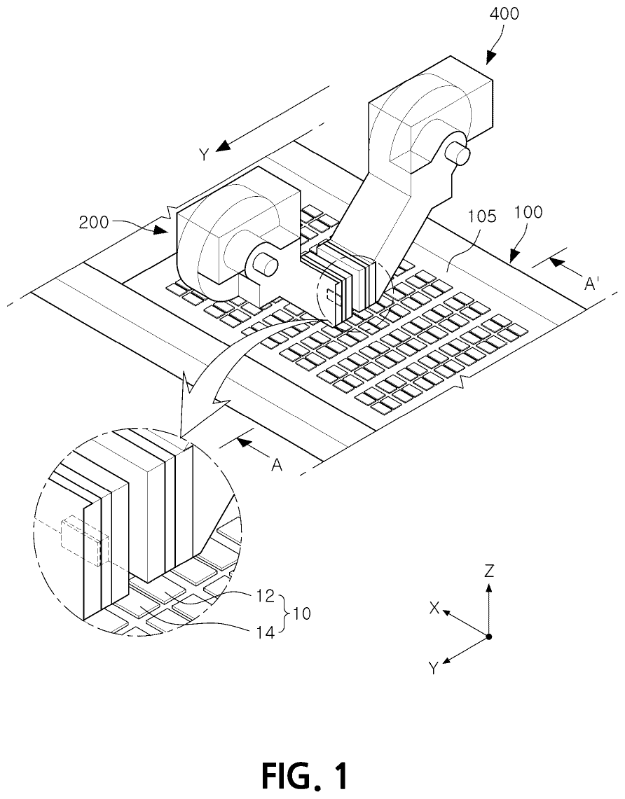

FIG. 1 is a perspective view schematically illustrating a die flip bonding device according to some example embodiments.

Referring to FIG. 1, a die flip bonding device 1 according to some example embodiments may include a substrate holder 100, a first moving body 200, and a second moving body 400.

Through the first moving body 200 and the second moving body 400 of the die flip bonding device 1, an uppermost die 125 located at an uppermost portion of a first die stack 12 on a plurality of die stacks 10 disposed on a substrate 105 on the substrate holder 100 may be flipped and moved to an upper surface of an uppermost die located at an uppermost portion of a second die stack 14 adjacent thereto.

First, for the convenience of understanding the die bonding device 1 of the present inventive concepts, directions will be defined.

A direction of progress of the first moving body 200 and the second moving body 400 of the die flip bonding device 1 may be referred to as a first direction (Y direction in the drawings, hereinafter referred to as ‘Y’), a direction, perpendicular to the first direction Y of the first moving body 200 and the second moving body 400 of the die flip bonding device 1, may be referred to as a second direction (Z direction in the drawings, hereinafter referred to as ‘Z’), and a direction of progress of the substrate holder 100 of the die flip bonding device 1 may be referred to as a third direction (X direction in the drawings, hereinafter referred to as ‘X’).

In this case, the first direction Y may be referred to as a direction of progress of flipping, based on the uppermost die 125, in which the flipping is progressing. The substrate holder 100 may progress in the third direction X, but may also be provided and fixed in any direction on a worktable.

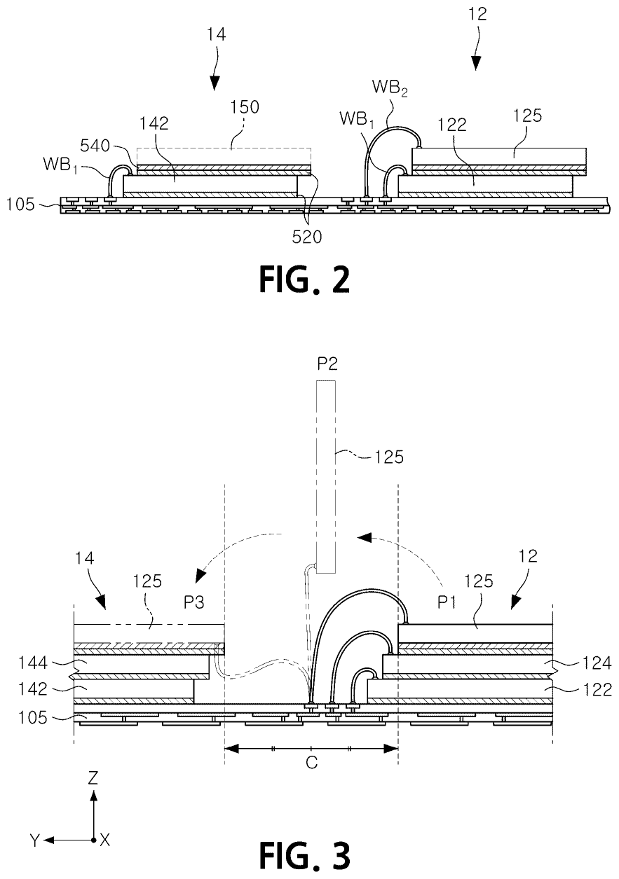

Before explaining a specific structure and a specific operation of the die flip bonding device 1 of the present inventive concepts, referring to FIG. 2, stacking appearance of the plurality of die stacks 10 on the substrate 105 that may be used in the die flip bonding device 1 of the present inventive concepts will first be explained.

FIG. 2 is a schematic cross-sectional view along line A-A′ of FIG. 1.

Referring to FIG. 2, a plurality of die stacks 10, 12, and 14 on a substrate 105 that may be used in a die flip bonding device 1 of the present inventive concepts may be disposed at a constant interval in the first direction Y.

Among the plurality of die stacks 10, the first die stack 12 and the second die stack 14 may include a plurality of dies stacked on the substrate 105.

The plurality of dies are at least two or more, and some example embodiments of FIG. 2 explains a case in which each of the die stacks 12 and 14 may include a first die, a second die, and two dies. In this case, the second die may become an uppermost die.

A first die 122 of a first die stack 12 may be bonded to the substrate 105 with a first adhesive film 520. The first die 122 of the first die stack 12 may be bonded to a second die 125 stacked on the first die 122 with the first adhesive film 520 and a second adhesive film 540. From the bottom to the top in a height direction, the substrate 105, the first adhesive film 520, the first die 122, the first adhesive film 520, the second adhesive film 540, and the second die 125 may be stacked. In this case, the second die may be an uppermost die 125 of the first die stack 12.

In addition, a first die 142 of a second die stack 14 disposed in a predetermined interval in the first direction Y in which flipping with the first die stack 12 is performed may be bonded to the substrate 105 with the first adhesive film 520. The first die 142 may be bonded to a second die 150 stacked on the first die 142 with the first adhesive film 520 and the second adhesive film 540. From the bottom to the top in a height direction, the substrate 105, the first adhesive film 520, the first die 142, the first adhesive film 520, the second adhesive film 540, and the second die 150 may be stacked. In this case, the second die 150 of the second die stack 14 may be a dummy die. The dummy die of the second die stack 14 may be removed before an uppermost die 125 of the first die stack 12 may be flipped onto an upper surface of an uppermost die of the second die stack 14.

When the dummy die of the second die stack 14 is removed, the uppermost die of the second die stack 14 to which the uppermost die 125 of the first die stack 12 is flipped may become the first die 142.

In this case, the first adhesive film 520 may include a low-temperature adhesive film that may be cured at about or exactly 120° C. or less, and the second adhesive film 540 may be a high-temperature adhesive film that may be cured at about or exactly 150° C. or less. In some example embodiments, the high-temperature adhesive film may be cured at a temperature greater than the curing temperature of the low-temperature adhesive film.

For example, when using the low-temperature adhesive film that may be cured at about or exactly 100° C., and the first adhesive film 520 is cured at about or exactly 100° C., in the first die stack 12, the substrate 105 and the first die 122, and the first adhesive film 520 and the second adhesive film 540 on the first die 122 may be bonded. Since the second adhesive film 540 is the high-temperature adhesive film that may not be cured at about or exactly 100° C., the second adhesive film 540 and the uppermost die 125 on the second adhesive film 540 may not be cured and bonded, but may be in a state of temporary bonding that may be separated by an external force at any time. That is, the first adhesive film 520 may be cured and strongly bonded, while the second adhesive film 540 is not cured and only weakly bonded.

In addition, the substrate 105 and the first die 142, and the first adhesive film 520 and the second adhesive film 540 on the first die 142 may be bonded. Since the second adhesive film 540 is the high-temperature adhesive film that may not be cured at about or exactly 100° C., the second adhesive film 540 and the second die 150 on the second adhesive film 540 may not be cured and bonded, but may be in a state of temporary bonding (e.g., weak bonding) that may be separated by an external force at any time. For example, the second die 150 may be separated from the temporary bonding without disturbing the remainder of the stack (e.g., the first die 142)

In some example embodiments, since the second die 150 is a dummy die, the uppermost die 125 of the first die stack 12 may be removed before being flipped by the first moving body 200 and the second moving body 400.

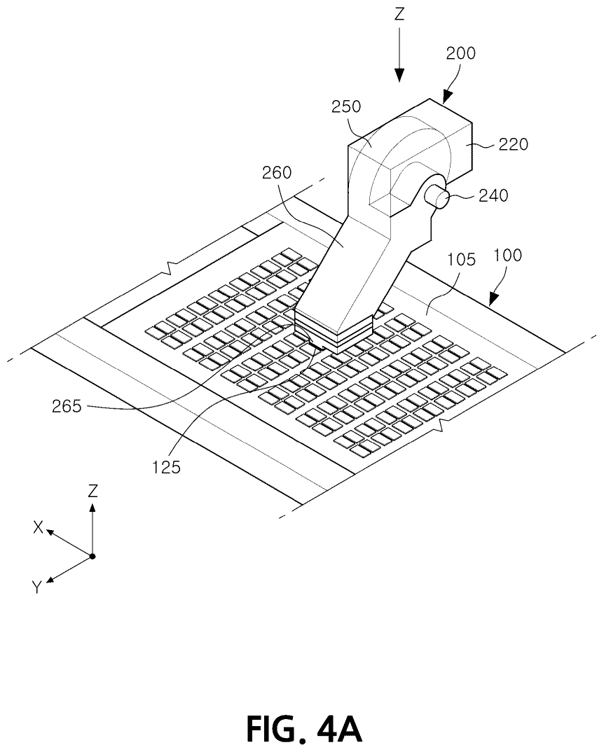

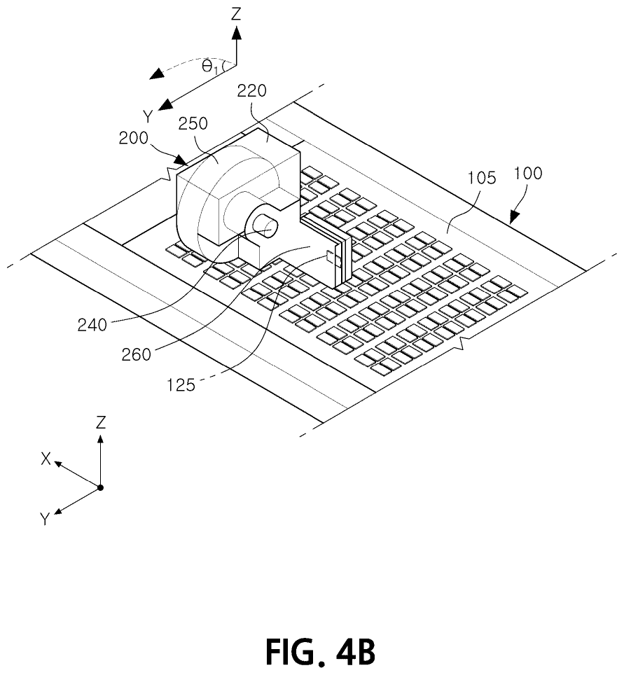

FIG. 3 is a cross-sectional view schematically illustrating a state in which an uppermost die of a die stack is flipped through a die flip bonding device. In addition, FIG. 4A is a schematic perspective view illustrating a state in which a first moving body moves to a first position and adsorbs a first uppermost die, FIG. 4B is a schematic perspective view illustrating a state in which a first moving body moves to a second position and half-flips a first uppermost die, and FIG. 4C is a schematic perspective view illustrating a state in which a second moving body moves to a second position and receives a first uppermost die from a first moving body. In addition, FIG. 4D is a schematic perspective view illustrating a state in which a first moving body moving while maintaining a state in which a second moving body receives a first uppermost die from a second position. FIG. 4E is a schematic perspective view illustrating a state in which a second moving body half-flips a first uppermost die from a second position to a third position on an upper surface of a second uppermost die of an adjacent die stack.

With reference to FIG. 3 and FIG. 4A to FIG. 4E, some example embodiments including structure and operation of a die flip bonding device 1 of the present inventive concepts will be described.

In the die flip bonding device 1 of FIG. 3, a plurality of die stacks 12 and 14 may be disposed at a constant interval in a direction of flipping on a substrate 105.

Unlike some example embodiments of FIG. 2, in some example embodiments of FIG. 3, a first die stack 12 may include a first die 122, a second die 124, and a third die 125, and a second die stack 14 may include a first die 142 and a second die 144.

In this case, the third die of the first die stack 12 becomes an uppermost die 125 of the first die stack 12, and the second die of the second die stack 14 becomes an uppermost die 144 of the second die stack 14. The third die of the second die stack 14 is illustrated as a dummy die in a removed state.

The uppermost die 125 located at an uppermost portion of the first die stack 12 disposed on the substrate 105 on a substrate holder 100 may be flipped and moved to an upper surface of the uppermost die 144 located at an uppermost portion of the second die stack 14, adjacent thereto, through a first moving body 200 and a second moving body 400 of the die flip bonding device 1.

Referring to FIG. 3, FIG. 4A and FIG. 4B, the first moving body 200 may move to a first position P1 to pick up the uppermost die 125 of the first die stack 12, and then may half-flip the uppermost die 125 of the first die stack 12 in the first direction Y to move the same to a second position P2.

FIG. 4A illustrates the first moving body 200 descending in the second direction Z to pick up the uppermost die 125 of the first die stack 12, and the uppermost die 125 of the first die stack 12 may be picked up by vacuum adsorption. FIG. 4B illustrates the first moving body 200 moving in the first direction Y and moving upwards in the second direction Z, to half-flip the uppermost die 125 from the first position P1 to the second position P2 in the first direction Y, substantially rotating or rotating the a corresponding about or exactly 90° to complete a full about or exactly 180° flip. In this case, the second position P2 may be located at a (e.g., substantially) intermediate position C of the first die stack 12 and the second die stack 14.

Since the half-flipping of the first moving body 200 moves in the first direction Y and rises in the second direction Z, the uppermost die 125 of the first die stack 12 may have an arc-shaped path at an angle of θ₁.

When the uppermost die 125 of the first die stack 12 half-flips to the second position P2, the first moving body 200 may wait, and the second moving body 400 may start moving.

Referring to FIG. 3, FIG. 4C and FIG. 4D, the second moving body 400 may move to the second position P2, and may receive the uppermost die 125 of the first die stack 12 from the first moving body 200. In this case, FIG. 4C illustrates a state in which the second moving body 400 moves in the first direction Y and receives the uppermost die 125 of the first die stack 12 by vacuum adsorption. FIG. 4D illustrates a state in which the second moving body 400 receives the uppermost die 125 of the first die stack 12 by vacuum adsorption, and then the first moving body 200 moves in the first direction Y such that the second moving body 400 may half-flip (e.g., about or exactly 180°).

Referring to FIGS. 3 and 4E, after the first moving body 200 moves, the second moving body 400 moves the uppermost die 125 of the first die stack 12 from the second position P2 to the first direction Y by half-flipping (e.g., about or exactly 180°) to a third position P3 above the uppermost die 144 of the second die stack 14.

In this case, since the half-flipping of the second moving body 400 may cause the uppermost die 125 of the half-flipped first die stack 12 to move in the first direction Y, and descend in the second direction Z, the uppermost die 125 of the first die stack 12 may have an arc-shaped path at an angle of θ₂.

Referring to FIGS. 4A and 4B, the first moving body 200 may move in the first direction Y and the second direction Z, perpendicular to the first direction. In some example embodiments, the first moving body 200 may include a first outer case 220, a first rotational axis 240, a first cam 250, and a first camshaft 260.

The first rotational axis 240 may be installed in the first outer case 220, and the first cam 250 may rotate along the first rotational axis 240. The rotation of the first cam 250 along the first rotational axis 240 may be about or exactly 90° rotation for half-flipping, and the rotation of the first cam 250 may be regulated to have a rotation range of about or exactly 90° by the first outer case 220.

The first camshaft 260 may extend from the first cam 250 to the uppermost die (125 and 145) of one of the plurality of die stacks 12 and 14, and the first camshaft 260 in an initial position may have an end surface 262 of the first camshaft 260 facing the uppermost die (125 and 145) at the first position P1.

The end surface 262 of the first camshaft 260 may include an adsorption surface 265 vacuum-adsorbing the uppermost die (125 and 145). The adsorption surface 265 may be provided and protruded to correspond to a size of the uppermost die (125 and 145).

When the first cam 250 of the first moving body 200 of some example embodiments moves the uppermost die 125 of the first die stack 12 at the first position P1 to the second position by rotating about or exactly 90° in the first direction Y, e.g., half-flipping, the first moving body 200 may move upwards in the second direction Z such that the first uppermost die 125 moves in an arc shape rising in the first direction Y.

Referring to FIGS. 4C, 4D, and 4E, the second moving body 400 may move in the first direction Y and the second direction Z, perpendicular to the first direction. In some example embodiments, the second moving body 400 may include a second outer case 420, a second rotational axis 440, a second cam 450, and a second camshaft 460.

The second rotation axis 440 may be installed in the second outer case 420, and the second cam 450 may rotate along the second rotation axis 440. The rotation of the second cam 450 along the second rotation axis 440 may be about or exactly 90° rotation for half-flipping, and the rotation of the second cam 450 may be regulated to have a rotation range of about or exactly 90° by the second outer case 420.

Since the uppermost die 125 of the first die stack 12 may be already rotated about or exactly 90° to the second position P2, the rotation of the second cam 450 along the second rotation axis 440 in the first direction Y becomes about or exactly 180° rotation. The second camshaft 460 may extend from the second cam 450 to the uppermost die 125 of the first die stack 12 half-flipped to the second position P2, and the second camshaft 460 in an initial position may have an end surface 462 of the second camshaft 460 facing the uppermost die 125 of the second position P2.

The end surface 462 of the second camshaft 460 may include an adsorption surface 465 vacuum-adsorbing the uppermost die 125 at the second position P2. The adsorption surface 465 may be provided and protruded to correspond to a size of the uppermost die 125.

When the second cam 450 of the second moving body 400 of some example embodiments moves the uppermost die 125 of the first die stack 12 at the second position P2 by further rotating about or exactly 90° in the first direction Y, e.g., half-flipping, to the third position P3, the second moving body 400 moves downwards in the second direction Z such that the first uppermost die 125 moves in an arc shape descending in the first direction Y.

In performing half-flipping from the first position P1 to the second position P2 by the first moving body 200 and half-flipping from the second position P2 to the third position P3 by the second moving body 400, the second position P2 may be located at the substantially intermediate position C between the first die stack 12 and the second die stack 14.

The second position P2 may be disposed at the substantially intermediate position C between the first die stack 12 and the second die stack 14, such that a phenomenon of wire-bonding connected to the uppermost die 125 of the first die stack 12 to be flipped and the substrate 105 being disconnected or interfered with does not occur.

In this case, the fact that the second position P2 may be located at the substantially intermediate position C between the first die stack 12 and the second die stack 14 means that the same thing may be included, including spacing, positional deviation, and measurement errors that occur during movement and rotation of the moving body (200 and 400).

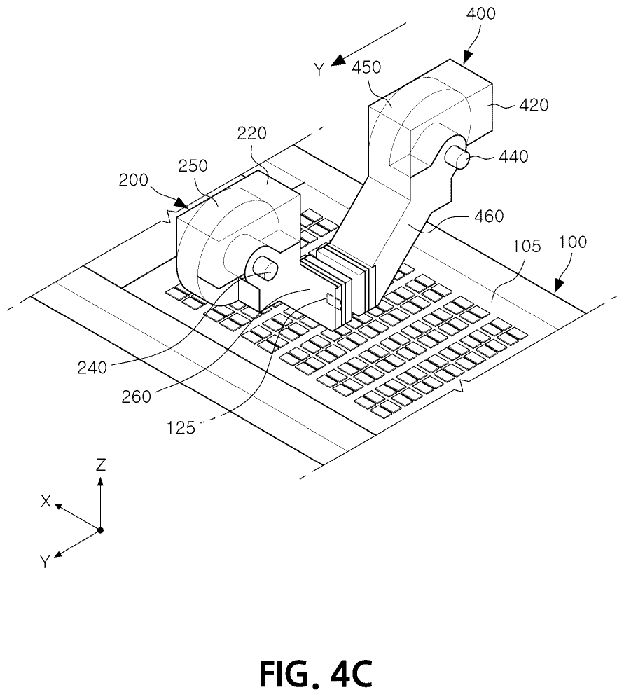

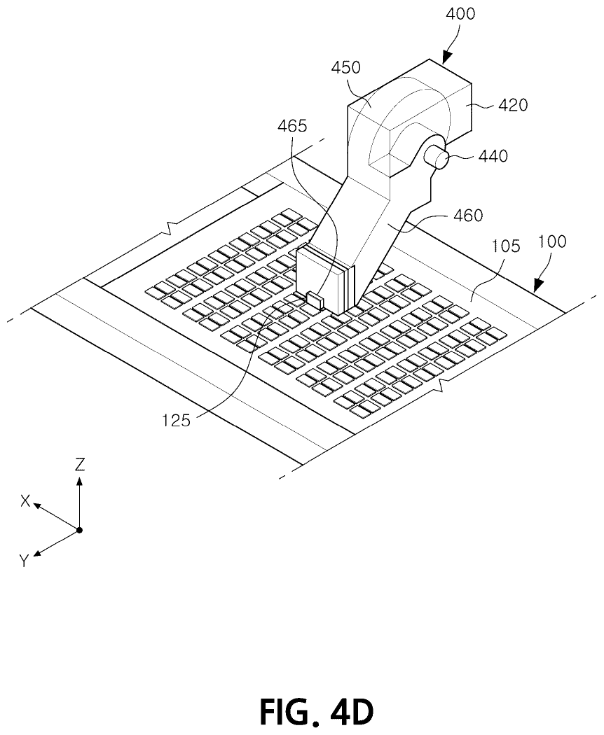

FIG. 5 is a schematic perspective view of a die flip bonding device including a third moving body 600 controlling a movement range of a second moving body 400, and FIG. 6 is a schematic perspective view illustrating a plurality of first moving bodies 200, 200′, and 200″, a plurality of second moving bodies 400, 400′, and 400″, and a plurality of third moving bodies 600, 600′, and 600″ in a die flip bonding device.

Referring to FIG. 5, a third moving body 600 may be disposed in a first′ direction Y′, parallel to the first direction Y of a first moving body 200 and a second moving body 400, and may regulate movement of the second moving body 400 in the first direction Y, movement of the second moving body 400 in the second direction Z, and rotation of the second moving body 400.

In some example embodiments, the third moving body 600 may include a third outer case 620, a third rotational shaft 640, a third cam 650, a third camshaft 660, and a connection shaft 680.

The third rotational shaft 640 may be installed in the third outer case 620, and the third cam 250 may rotate along the third rotational shaft 640. The rotation of the third cam 650 along the third rotational shaft 640 may be about or exactly 90° rotation for half-flipping of the second moving body 400, and the rotation of the third cam 650 may be regulated to have a rotation range of about or exactly 90° by the third outer case 620.

The third camshaft 660 may extend from the third cam 650 at an angle at which the second camshaft 460 extends from the second cam 450, such that the third camshaft 660 may extend parallel to the second camshaft 460.

The connection shaft 680 may extend from the third camshaft 660 to the second camshaft 460 to connect the third camshaft 660 and the second camshaft 460. The third moving body 600 may move and rotate by the connection shaft 680, to control the second moving body 400.

In the third moving body 600 of some example embodiments, the connection shaft 680 may be linear, and the third camshaft 660 and the second camshaft 460 may be disposed in parallel, but are not limited thereto. When the second moving body 400 has a connecting shape that may control movement in the first direction and movement in the second direction, the third moving body 600 may be disposed to be staggered from the second moving body 400, and a shape of the connection shaft 680 is not limited to being linear.

Referring to FIG. 6, a die flip bonding device equipped with a plurality of first moving bodies 200, 200′, and 200″, a plurality of second moving bodies 400, 400′, and 400″, and a plurality of third moving bodies 600, 600′, and 600″ is disclosed.

The die flip bonding device of FIG. 6 may be equipped with the plurality of first moving bodies 200, 200′, and 200″, the plurality of second moving bodies 400, 400′, and 400″, and the plurality of third moving bodies 600, 600′, and 600″, and may half-flip uppermost dies of a continuous die stack simultaneously or sequentially. Herein, simultaneously may refer to events happening at the same time or at about the same time, e.g., within 0.1 seconds of one another.

Also, in some example embodiments of FIG. 6, similarly to some example embodiments of FIG. 5, the plurality of first moving bodies 200, 200′, and 200″ and the plurality of second moving bodies 400, 400′, and 400″ may be sequentially disposed in the first direction Y.

In addition, the third moving body 600 may be disposed in the first′ direction Y′, parallel to the first direction Y of the first moving body 200 and the second moving body 400, and may regulate movement of the second moving body 400 in the first direction Y, movement of the second moving body 400 in the second direction Z, and rotation of the second moving body 400.

In some example embodiments, there may be more than the three first moving bodies 200, 200′, and 200″ and three second moving bodies 400, 400′, and 400″ shown according to the inventive concepts.

### Method for manufacturing Semiconductor Package

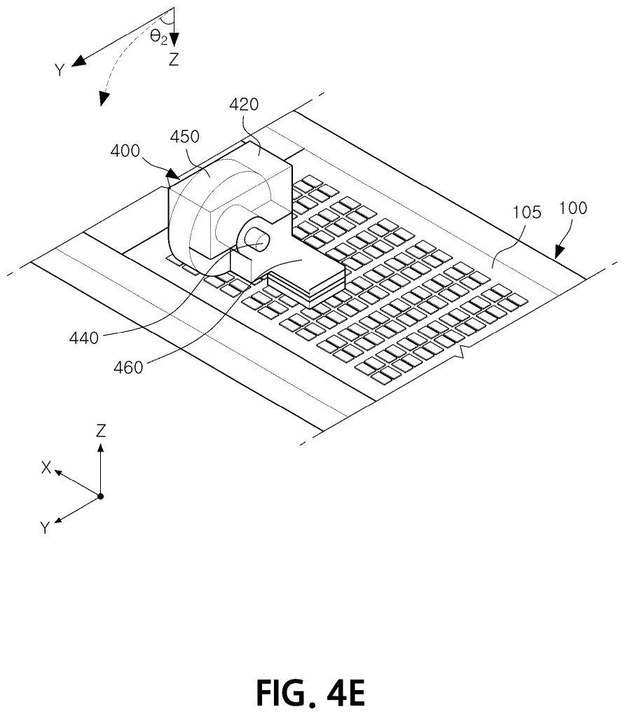

FIG. 7 is a flow chart of a method for manufacturing a semiconductor package according to some example embodiments.

Referring to FIG. 7, a method for manufacturing a semiconductor package according to some example embodiments may include bonding a substrate 105 and a first die (142 and 122) on the substrate 105 with a low-temperature adhesive film 520 (S10), bonding the first die (142 and 122) and a second die (144 and 124) on the first die (142 and 122) with the low-temperature adhesive film 520 (S20), bonding the first die (142 and 122) and an uppermost die (150 and 125) or the second die (144 and 124), and the uppermost die (150 and 125) on the first die (142 and 122) or the second die (144 and 124), with the low-temperature adhesive film 520 and a high-temperature adhesive film 540 (S40), performing the low-temperature curing process to cure the low-temperature adhesive film 520 (S60), mounting the uppermost die (150 and 125) on an upper surface of the uppermost die (150 and 125) of an adjacent die stack (14 and 12) by picking up the uppermost die (150 and 125) and then flipping the same in a direction of performing the flipping (S80), and molding the substrate 105 and sawing and separating each die stack 12 and 14 (S120).

The method of FIG. 7 may use the die flip bonding device 1 of FIGS. 1 to 6, but is not limited to a method of flipping an uppermost die 125 of a first die stack 12 wire-bonded (WB₃) with a substrate 105 to the upper surface of an uppermost die 144 of a second die stack 14 adjacent thereto.

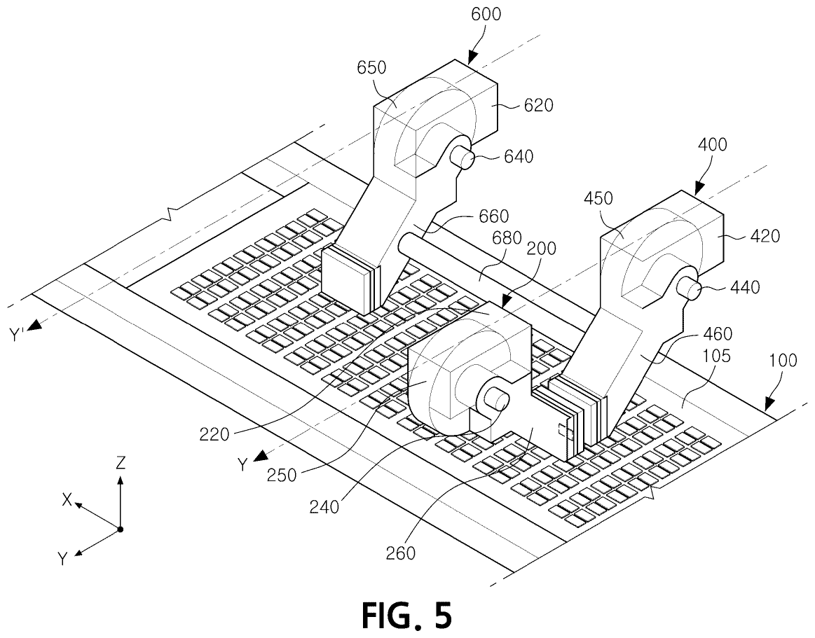

Hereinafter, a method for manufacturing a semiconductor package will be described in detail with reference to FIGS. 8 to 14.

FIG. 8 may be a schematic cross-sectional view illustrating a process of mounting a first die (122 and 142) on a substrate 105 in a method for manufacturing a semiconductor package according to some example embodiments.

Referring to FIG. 8, a first die (122 and 142) may be bonded to a substrate 105 using a first adhesive film 520. In this case, the first adhesive film 520 may be a die attach film (DAF) of an epoxy component including a low-temperature adhesive film that may be cured at about or exactly 120° C. or less.

The first die (122 and 142) may be disposed at a constant interval in a direction in which flipping is performed. In some example embodiments, the first die (122 and 142) may be disposed at a patterned interval (e.g., a spacing of 1, 3, 1) or an irregular interval.

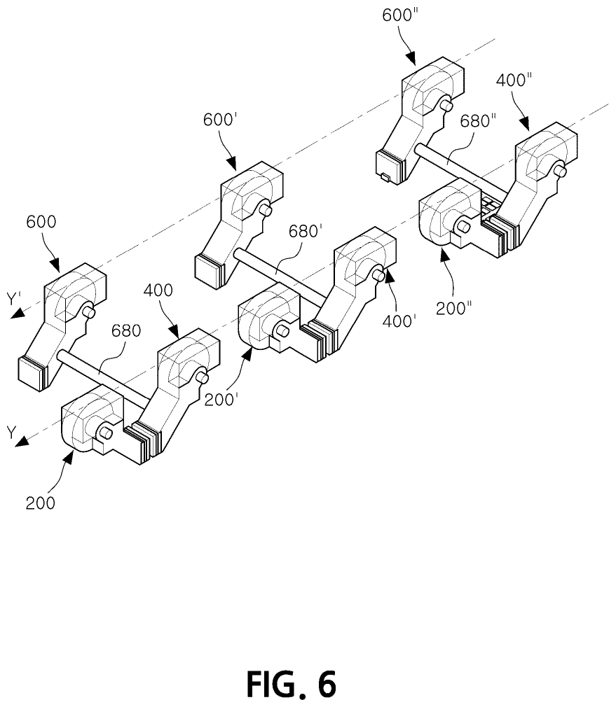

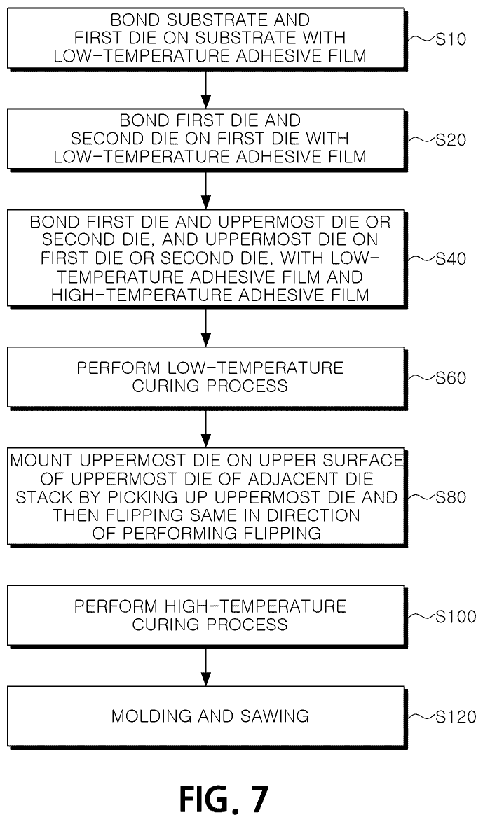

FIG. 9 is a schematic cross-sectional view illustrating a process of stacking an uppermost die on a die, in a method for manufacturing a semiconductor package according to some example embodiments, and FIG. 10 is a schematic cross-sectional view illustrating a process of wire-bonding the stacked die of FIG. 9 and a substrate, in a method for manufacturing a semiconductor package according to some example embodiments.

Referring to FIGS. 9 and 10, in some example embodiments, two dies including a first die (122 and 142) and an uppermost die (125 and 150) may be stacked on a substrate 105 to manufacture a die stack (12 and 14) wire-bonded to the substrate 105.

A first die 122 and an uppermost die 125 of a first die stack 12 and the first die 142 and an uppermost die 150 of a second die stack 14 may be bonded by disposing a first adhesive film 520 and a second adhesive film 540 therebetween.

In this case, in the uppermost die (125 and 150), the uppermost die 150 adjacent to an end portion of the substrate 105 in a direction in which a flip process is performed may include a dummy die, and the dummy die may not be bonded to the substrate 105 by wire-bonding.

The first adhesive film 520 may include a low-temperature adhesive film that may be cured at about or exactly 120° C. or less, and the second adhesive film 540 may include a high-temperature adhesive film that may be cured at about or exactly 150° C. or less.

When the first die 122 and the uppermost die 125 of the first die stack 12 and the first die 142 and the uppermost die 150 of the second die stack 14 are bonded by disposing the first adhesive film 520 and the second adhesive film 540 therebetween, a low-temperature curing process (e.g., operation S60) may be performed.

For example, when using a low-temperature adhesive film that may be cured at about or exactly 100° C., and the first adhesive film 520 is cured at about or exactly 100° C., in the first die stack 12, the substrate 105 and the first die 122, and the first adhesive film 520 and the second adhesive film 540 on the first die 122 may be bonded. Since the second adhesive film 540 is a high-temperature adhesive film that not cured at about or exactly 100° C., the second adhesive film 540 and the uppermost die 125 on the second adhesive film 540 may be in a state of temporary bonding that may be separated by an external force at any time.

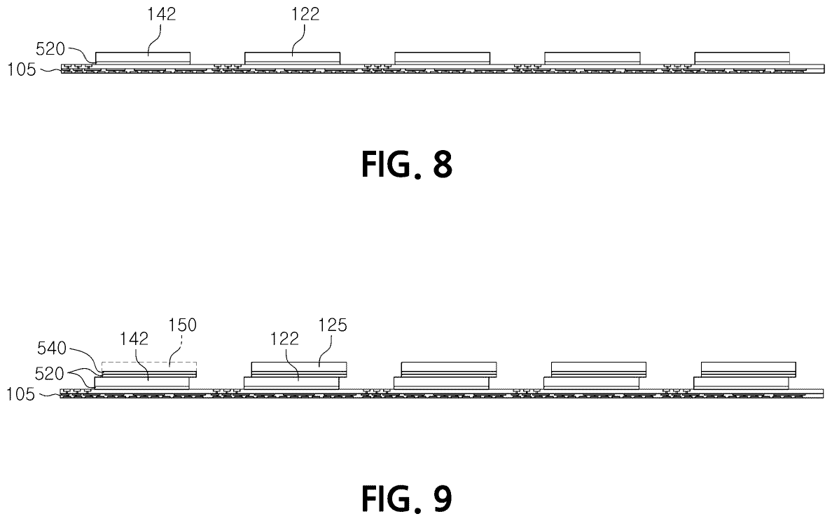

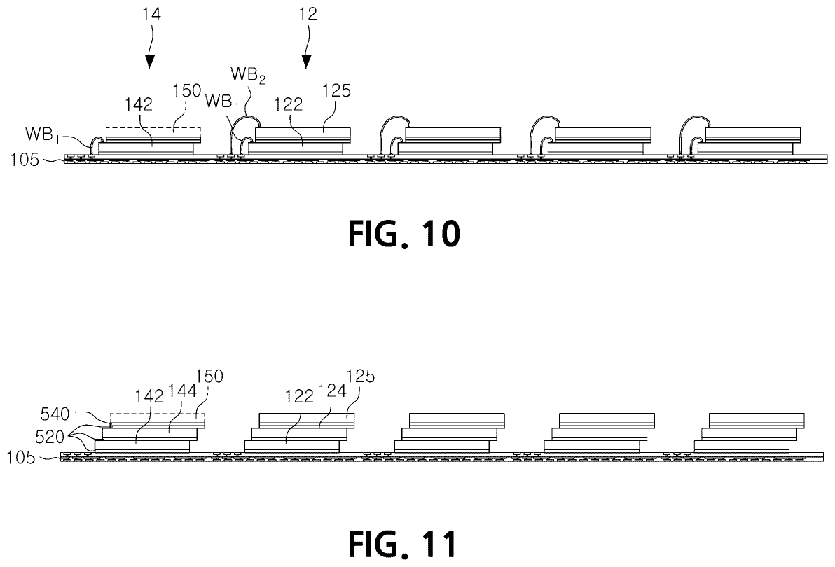

FIG. 11 is a schematic cross-sectional view illustrating a process of stacking an uppermost die after a plurality of dies are stacked, in a method for manufacturing a semiconductor package according to some example embodiments, and FIG. 12 is a schematic cross-sectional view illustrating a process of wire-bonding the plurality of dies and the substrate of FIG. 10, in a method for manufacturing a semiconductor package according to some example embodiments.

In some example embodiments of FIGS. 11 and 12, unlike some example embodiments of FIGS. 9 and 10, in die stacks 12 and 14, three dies, e.g., a first die (122 and 142), a second die (124 and 144), and a third die (125 and 150), may be stacked respectively.

In this case, a substrate 105 and the first die (122 and 142), and the first die (122 and 142), and the second die (124 and 144) may be bonded with a first adhesive film 520, and the second die (124 and 144) and the third die (125 and 150) may be bonded with the first adhesive film 520 and a second adhesive film 540.

The first adhesive film 520 and the second adhesive film 540 of some example embodiments may perform the same functions as those of some example embodiments of FIGS. 9 and 10.

In this case, the third die (125 and 150) may be an uppermost die, and the uppermost die 150 adjacent to an end portion of the substrate 105 in a direction of a flip process may include a dummy die, and the dummy die may not be bonded to the substrate 105 by wire-bonding.

After an uppermost die (125 and 150) is stacked or after wire-bonding (WB₁, WB₂, and WB₃) are performed, a low-temperature curing process (e.g., operation S60) may be performed.

When the low-temperature curing process (e.g., operation S60) is performed, as seen in some example embodiments ents of FIGS. 9 and 10, the uppermost die (125 and 150) may be separated from the second die (124 and 144) by an external force at any time in a state of temporary bonding.

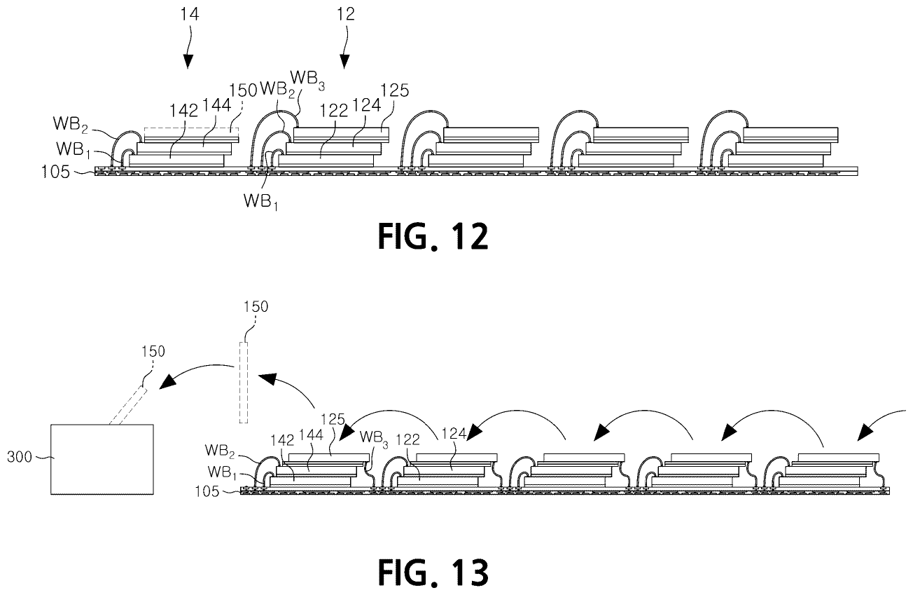

FIG. 13 is a schematic cross-sectional view illustrating a process of flipping and mounting an upper die of a stacked die on an upper surface of an adjacent die stack, in a method for manufacturing a semiconductor package according to some example embodiments.

When an uppermost die (150 and 125) is flipped and mounted on an upper surface of an adjacent die stack, an uppermost die 150 adjacent to an end portion of a substrate 105 in a direction of a flip process may be discarded as a dummy die into a dummy box 300 adjacent to the substrate 105.

When the dummy die is discarded, a second die of a second die stack 14 in which the dummy die was located may become an uppermost die 144.

In addition, an uppermost die 125 of a first die stack 12 may be flipped to an upper surface of the uppermost die 144 of the second die stack 14 adjacent thereto, such that a die stack of three dies may be stacked overall, and a die stack of an end portion, opposite to a direction of flipping the substrate 105 may become a die stack of two dies.

After the flipping is completed in this manner, a high-temperature curing process (e.g., operation S100) may be performed overall. A second adhesive film may be cured by the high-temperature curing process, such that a new uppermost die 125 flipped from a dummy stack adjacent to a second die (144 and 124) may be cured and bonded.

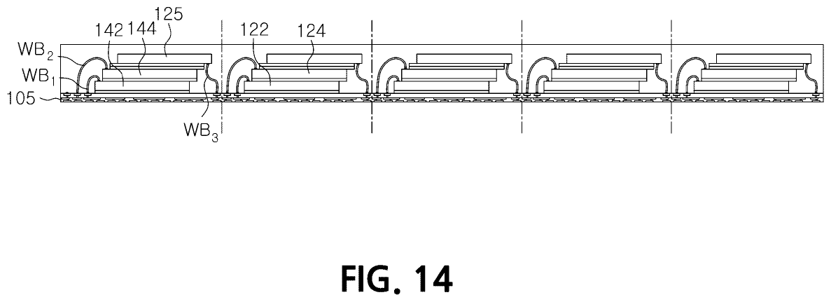

FIG. 14 is a schematic cross-sectional view illustrating a process of molding and sawing a die stack on an upper portion of a substrate, in a method for manufacturing a semiconductor package according to some example embodiments.

After all stacked dies forming a die stack (12 and 14) are cured, molding and sawing processes of FIG. 14 may be performed. A molding member may include, for example, an epoxy mold compound (EMC).

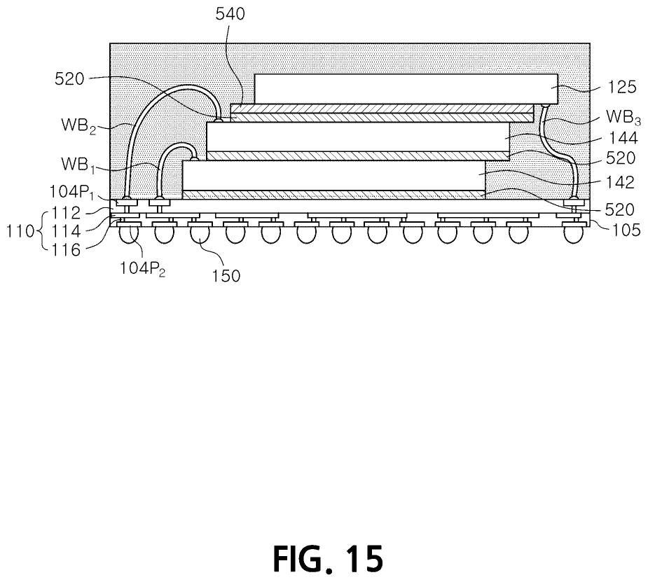

FIG. 15 is a schematic cross-sectional view of a semiconductor package manufactured by a method for manufacturing a semiconductor package according to some example embodiments.

In FIG. 14, when a molded substrate 105 is sawed, a semiconductor package may be formed in which three dies 142, 144, and 125 are stacked on the substrate 105. When the semiconductor package is manufactured in this manner, a wire loop of a first die 142 and a wire loop of a second die 144 may be bonded by protruding upwardly from the first die 142 and the second die 144, respectively, but a wire loop of an uppermost die 125 may not protrude upwardly from the uppermost die 125, but may be directly bonded to the substrate on a lower surface of the uppermost die 125.

The semiconductor package of some example embodiments may reduce usages of molding materials, and may reduce a height of the semiconductor package because the semiconductor loop does not protrude above the uppermost die 125.

Depending on a type of die, this semiconductor package may be a single semiconductor chip, and may be combined with other packages and applied as other packages.

The substrate 105 may be provided with a wire-bonding pad 104P₁ that may be wire-bonded to dies, and may be provided with a recombining pad 104P₂ to which solder balls are combined for combining with other substrates. In addition, the substrate 105 may be provided with a redistribution layer 112, and a redistribution line pattern 114 and a redistribution via 116 may be provided within the redistribution layer 112 such that the substrate 105 may be electrically connected to the recombining pad 104P₂ connecting the die to other substrates.

According to a die flip bonding device and a method for manufacturing a semiconductor package of the present inventive concepts, an uppermost die of a die stack may be flipped, without damaging a wire, in the die stack in which a substrate and a die are already wire-bonded.

In addition, a semiconductor package having a shape in which an uppermost die is flipped down may be manufactured, and a lower surface of the uppermost die and a substrate are wire-bonded such that a loop structure of the wire-bonding does not protrude from the upper surface of the uppermost die, thereby reducing a volume of the semiconductor package.

In addition, a continuous die stack may be provided on a substrate, and an uppermost die of the die stack may be automatically flipped to an adjacent uppermost die, adjacent thereto, in a direction of performing the flipping, thereby improving manufacturing speed and productivity.

When the terms “about” or “substantially” are used in this specification in connection with a numerical value, it is intended that the associated numerical value includes a manufacturing or operational tolerance (e.g., ±10 %) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10 %) around the stated numerical values or shapes.

While example embodiments have been illustrated and described above, it will be apparent to those skilled in the art that modifications and variations could be made without departing from the scope of the present inventive concepts as defined by the appended claims.

What is claimed is:

1. A die flip bonding device comprising:
a substrate holder configured to provide a substrate including a plurality of die stacks having a gap in a first direction, the plurality of die stacks being wire-bonded;
a first moving body configured to move to a first position to pick up a first uppermost die of a first die stack among the plurality of die stacks, and then half-flip the first uppermost die in the first direction to move the first uppermost die to a second position; and
a second moving body configured to move to the second position to receive the first uppermost die of the first die stack from the first moving body, and after the movement of the first moving body, half-flip the first uppermost die of the first die stack in the first direction at the second position to move the first uppermost die to a third position above an uppermost die of a second die stack among the plurality of die stacks.

2. The die flip bonding device of claim 1, wherein
the first moving body is configured to move in the first direction and in a second direction, perpendicular to the first direction,
the first moving body comprises,
a first outer case;
a first rotational axis in the first outer case;
a first cam configured to rotate along the first rotational axis; and
a first camshaft configured to extend from the first cam to an uppermost die of the plurality of die stacks, and
an end surface of the first camshaft includes an adsorption surface configured to vacuum-adsorb the uppermost die.

3. The die flip bonding device of claim 2, wherein, based on the first cam rotating the first uppermost die of the first die stack at the first position by 90° in the first direction, to half-flip and move the first uppermost die to the second position, the first moving body is configured to move upwards in the second direction to move the first uppermost die in an arc shape rising in the first direction.

4. The die flip bonding device of claim 2, wherein
the second moving body is configured to move in the first direction and in the second direction, perpendicular to the first direction, and
the second moving body comprises,
a second outer case;
a second rotational axis in the second outer case;
a second cam configured to rotate along the second rotational axis; and
a second camshaft configured to extend from the second cam to the first uppermost die half-flipped and move to the second position, and
an end surface of the second camshaft includes an adsorption surface vacuum-configured to absorb the first uppermost die.

5. The die flip bonding device of claim 4, wherein, based on the second cam rotating the first uppermost die of the first die stack half-flipped at the second position by 90° in the first direction, to move the first uppermost die to the third position, the second moving body is configured to move downwards in the second direction to move the first uppermost die of the first die stack in an arc shape descending in the first direction.

6. The die flip bonding device of claim 4, further comprising a third moving body disposed in a first′ direction, parallel to the first direction of the first moving body and the second moving body, the third moving body configured to regulate movement of the second moving body in the first direction, movement of the second moving body in the second direction, and rotation of the second moving body.

7. The die flip bonding device of claim 6, wherein the third moving body comprises
a third outer case;
a third rotational axis in the third outer case;
a third cam configured to rotate along the third rotational axis;
a third camshaft extending parallel to the second camshaft from the third cam; and
a connection shaft extending from the third camshaft to the second camshaft.

8. The die flip bonding device of claim 7, wherein the first moving body, the second moving body, and the third moving body are provided in plural, and simultaneously or sequentially automate and half-flip an uppermost die of a continuous die stack.

9. The die flip bonding device of claim 1, wherein
the plurality of die stacks on the substrate holder comprises at least two dies stacked on the substrate,
the substrate and a first die stacked on the substrate or the first die and a second die stacked on the first die are bonded with a first adhesive film,
the first die or the second die and the uppermost die are bonded with the first adhesive film and a second adhesive film,
the first adhesive film includes a low-temperature adhesive film that is cured at 120°C. or less, and
the second adhesive film includes a high-temperature adhesive film that is cured at 150°C. or less and at a temperature greater than a curing temperature of the low-temperature adhesive film.

10. The die flip bonding device of claim 1, wherein the second position is at an intermediate position between the first die stack and the second die stack.

11. A die flip bonding device for flipping and stacking an uppermost die of at least one die stack onto an uppermost die of an adjacent die stack, in a plurality of die stacks in which a substrate is connected to a plurality of dies stacked on the substrate by wire-bonding, comprising:
a first moving body configured to simultaneously move upwards in a first direction and a second direction, perpendicular to the first direction, to pick up an uppermost die of a first die stack, among the plurality of die stacks, to half-flip the picked uppermost die toward a second die stack adjacent thereto; and
a second moving body configured to simultaneously move downwards in the first direction and the second direction, to receive the half-flipped uppermost die of the first die stack to half-flip the received uppermost die on an upper surface of an uppermost die of the second die stack.

12. The die flip bonding device of claim 11, wherein the half-flipping of the first moving body is configured to move the uppermost die of the first die stack in the first direction and rise the uppermost die in the second direction, to have an arc-shaped path.

13. The die flip bonding device of claim 11, wherein the half-flipping of the second moving body configured to move the half-flipped uppermost die of the first die stack in the first direction and descend the half-flipped uppermost die in the second direction to have an arc-shaped path.

14. The die flip bonding device of claim 11, wherein
the first moving body comprises
a first outer case;
a first rotational axis in the first outer case;
a first cam configured to rotate along the first rotational axis; and
a first camshaft extending from the first cam to the uppermost die of the first die stack, and
an end surface of the first camshaft includes an adsorption surface configured to vacuum-adsorb the uppermost die.

15. The die flip bonding device of claim 11, wherein
the second moving body comprises
a second outer case;
a second rotational axis installed in the second outer case;
a second cam configured to rotate along the second rotational axis; and
a second camshaft extending from the second cam to the half-flipped uppermost die of the first die stack, and
an end surface of the second camshaft includes an adsorption surface configured to vacuum-absorb the uppermost die of the first die stack.

16. The die flip bonding device of claim 15, further comprising a third moving body disposed in a third direction, parallel to the first direction, and configured to regulate movement of the second moving body in the first direction, movement of the second moving body in the second direction, and rotation of the second moving body.

17. The die flip bonding device of claim 16, wherein
the third moving body comprises
a third outer case;
a third rotational axis in the third outer case;
a third cam configured to rotate along the third rotational axis;
a third camshaft extending parallel to the second camshaft from the third cam; and
a connection shaft extending from the third camshaft to the second camshaft, and coupled to the second camshaft.

18. The die flip bonding device of claim 17, wherein the first moving body, the second moving body, and the third moving body are provided in plural, and are configured to simultaneously or sequentially automate and half-flip an uppermost die of a continuous die stack.

19. The die flip bonding device of claim 11, wherein
at least one of the plurality of die stacks comprises at least two dies stacked on the substrate,
the substrate and a first die stacked on the substrate or the first die and a second die stacked on the first die are bonded with a first adhesive film,
the first die or the second die and the uppermost die are bonded with the first adhesive film and a second adhesive film,
the first adhesive film includes a low-temperature adhesive film that is cured at 120°C. or less, and
the second adhesive film includes a high-temperature adhesive film that is cured at 150°C. or less and at a temperature greater than a curing temperature of the low-temperature adhesive film.

20. The die flip bonding device of claim 11, wherein the half-flipping of the first moving body is performed such that the uppermost die of the first die stack is located at an intermediate position between the first die stack and the second die stack.
